(19) United States
(12) Patent Application Publication
(10) Pub. No.: US 2015/0194831 A1
(43) Pub. Date: Jul. 9, 2015

(54) ELECTRIC TOOL

(71) Applicant: My Hand Industrial Co.,Ltd., Nan Tou County (TW)

(72) Inventors: Chien-Kuo Lin, Nan Tou County (TW); Hsueh-Fu Chang, Nan Tou County (TW); Yun-Hong Hu, Nan Tou County (TW)

(21) Appl. No.: 14/299,690

(22) Filed: Jun. 9, 2014

(30) Foreign Application Priority Data
Jan. 6, 2014 (TW) 103200205

(51) Int. Cl. H02J 7/00; G01R 19/165; G01R 19/00; B25F 5/00

(52) U.S. Cl. CPC H02J 7/0042; B25F 5/00; H02J 7/007; H02J 7/0047; G01R 19/165; G01R 19/0084; H02J 2007/0049

(57) ABSTRACT

If a voltage of an electricity storage unit of an electric tool is not greater than a first threshold voltage, the electricity storage unit is charged with a first constant trickle current until the voltage of the electricity storage unit is greater than the first threshold voltage. Then, the electricity storage unit is charged with a constant current until the voltage of the electricity storage unit is greater than or equal to a second threshold voltage. Then, the electricity storage unit is charged with a constant voltage until a current for charging the electricity storage unit is equal to a second constant trickle current, and then the electricity storage unit stops being charged. The electricity storage unit is float charged automatically when a transient voltage of the electricity storage unit is decreased and is less than or equal to a third threshold voltage.

### BACKGROUND OF THE INVENTION

1. Field of the Invention

The present invention relates to an electric tool, and especially relates to an improved electric tool.

2. Description of the Related Art

Electric tools, such as electric screwdrivers, are used widely for assembling equipment, machines or objects, so that the speed of the assembling is improved greatly. Therefore, the electric tools are very important. However, the charging method for the conventional electric tool is inconvenient and the charging efficiency is not good.

### SUMMARY OF THE INVENTION

In order to solve the above-mentioned problems, an object of the present invention is to provide an electric tool.

In order to achieve the object of the present invention mentioned above, the electric tool is applied to a direct current voltage supply apparatus. The electric tool is electrically connected to the direct current voltage supply apparatus. The electric tool comprises a universal serial bus unit, a charging unit, a control unit, an electricity storage unit, a voltage detection unit, a switch unit and a motor unit. The universal serial bus unit is electrically connected to the direct current voltage supply apparatus. The charging unit is electrically connected to the universal serial bus unit. The control unit is electrically connected to the charging unit. The electricity storage unit is electrically connected to the charging unit. The voltage detection unit is electrically connected to the electricity storage unit and the control unit. The switch unit is electrically connected to the electricity storage unit. The motor unit is electrically connected to the switch unit. The voltage detection unit detects a voltage of the electricity storage unit and then informs the control unit of the voltage of the electricity storage unit. If the voltage of the electricity storage unit is not greater than a first threshold voltage, the control unit is configured to control the charging unit to charge the electricity storage unit with a first constant trickle current until the voltage of the electricity storage unit is greater than the first threshold voltage. If the voltage of the electricity storage unit is greater than the first threshold voltage, the control unit is configured to control the charging unit to charge the electricity storage unit with a constant current until the voltage of the electricity storage unit is greater than or equal to a second threshold voltage. If the voltage of the electricity storage unit is greater than or equal to the second threshold voltage, the control unit is configured to control the charging unit to charge the electricity storage unit with a constant voltage until a current for charging the electricity storage unit is equal to a second constant trickle current, and then the charging unit stops charging the electricity storage unit. After the electricity storage unit is full charged, when a transient voltage of the electricity storage unit is decreased and is less than or equal to a third threshold voltage, the control unit is configured to control the charging unit to float charge the electricity storage unit until the current for charging the electricity storage unit is equal to a third constant trickle current and until the transient voltage of the electricity storage unit is greater than the third threshold voltage. Then the charging unit stops float charging the electricity storage unit. The second threshold voltage is greater than the first threshold voltage. The second threshold voltage is greater than the third threshold voltage. The third threshold voltage is greater than the first threshold voltage. The constant current is greater than the first constant trickle current. The constant current is greater than the second constant trickle current. The constant current is greater than the third constant trickle current.

The efficiency of the present invention is that the charging method for the electric tool is more convenient and the charging efficiency is improved.

### BRIEF DESCRIPTION OF DRAWING

FIG. 1 shows a block diagram of the first embodiment of the electric tool of the present invention.

FIG. 2 shows a block diagram of the second embodiment of the electric tool of the present invention.

### DETAILED DESCRIPTION OF THE INVENTION

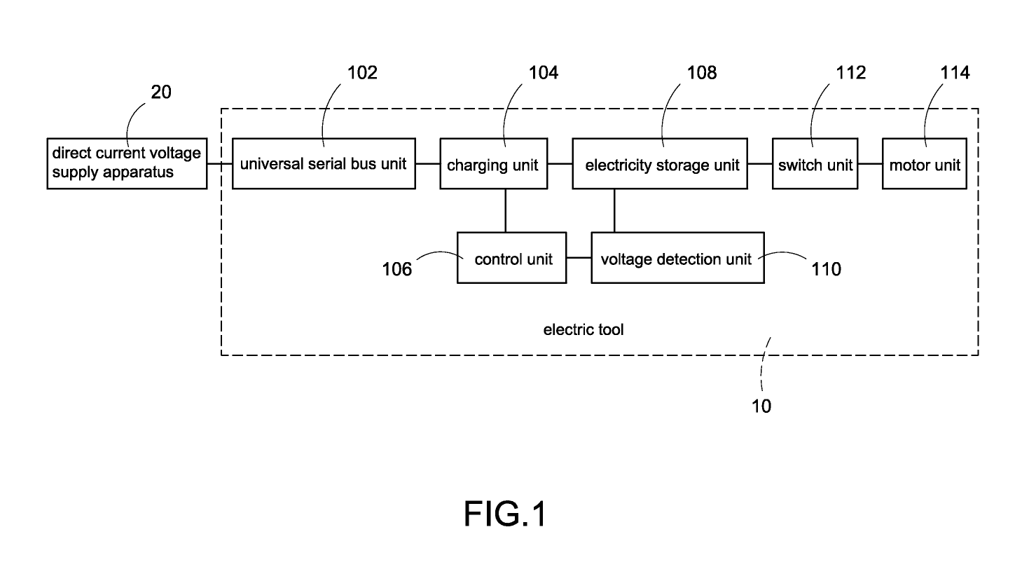

FIG. 1 shows a block diagram of the first embodiment of the electric tool of the present invention. An electric tool 10 is applied to a direct current voltage supply apparatus 20. The electric tool 10 is electrically connected to the direct current voltage supply apparatus 20.

The electric tool 10 comprises a universal serial bus unit 102, a charging unit 104, a control unit 106, an electricity storage unit 108, a voltage detection unit 110, a switch unit 112 and a motor unit 114.

The universal serial bus unit 102 is electrically connected to the direct current voltage supply apparatus 20. The charging unit 104 is electrically connected to the universal serial bus unit 102. The control unit 106 is electrically connected to the charging unit 104. The electricity storage unit 108 is electrically connected to the charging unit 104. The voltage detection unit 110 is electrically connected to the electricity storage unit 108 and the control unit 106. The switch unit 112 is electrically connected to the electricity storage unit 108. The motor unit 114 is electrically connected to the switch unit 112.

The voltage detection unit 110 detects a voltage of the electricity storage unit 108 and then informs the control unit 106 of the voltage of the electricity storage unit 108. The charging process is as follows.

If the voltage of the electricity storage unit 108 is not greater than a first threshold voltage, the control unit 106 is configured to control the charging unit 104 to charge the electricity storage unit 108 with a first constant trickle current until the voltage of the electricity storage unit 108 is greater than the first threshold voltage.

If the voltage of the electricity storage unit 108 is greater than the first threshold voltage, the control unit 106 is configured to control the charging unit 104 to charge the electricity storage unit 108 with a constant current until the voltage of the electricity storage unit 108 is greater than or equal to a second threshold voltage.

If the voltage of the electricity storage unit 108 is greater than or equal to the second threshold voltage, the control unit 106 is configured to control the charging unit 104 to charge the electricity storage unit 108 with a constant voltage until a current for charging the electricity storage unit 108 is equal to a second constant trickle current, and then the charging unit 104 stops charging the electricity storage unit 108.

After the electricity storage unit 108 is full charged, when a transient voltage of the electricity storage unit 108 is decreased and is less than or equal to a third threshold voltage, the control unit 106 is configured to control the charging unit 104 to float charge the electricity storage unit 108 until the current for charging the electricity storage unit 108 is equal to a third constant trickle current and until the transient voltage of the electricity storage unit 108 is greater than the third threshold voltage. Then the charging unit 104 stops float charging the electricity storage unit 108.

The charge and discharge of the battery is an active chemical reaction of the reduction and oxidation. The electric potential of the battery is floating upward when the battery is charged. The voltage of the battery will be decreased when stopping charging. This is called the transient voltage. The charging unit 104 of the present invention has the function of automatic recharge. Therefore, when the transient voltage of the battery which is full charged is decreased and less than the third threshold voltage, the charging unit 104 will float charge the battery automatically until the constant current for charging is equal to the third constant trickle current. Then the charging unit 104 stops charging the battery. When the voltage of the battery is decreased again, the automatic recharge procedure mentioned above will proceed again until the transient voltage of the battery is greater than the third threshold voltage.

Moreover, the second threshold voltage is greater than the first threshold voltage. The second threshold voltage is greater than the third threshold voltage. The third threshold voltage is greater than the first threshold voltage. The constant current is greater than the first constant trickle current. The constant current is greater than the second constant trickle current. The constant current is greater than the third constant trickle current.

Moreover, the first threshold voltage is, for example but not limited to, 2.5 volts. The second threshold voltage is, for example but not limited to, stable 3.6 volts. The third threshold voltage is, for example but not limited to, 3.3 volts. The first constant trickle current is, for example but not limited to, 100 milliamperes. The second constant trickle current is, for example but not limited to, 100 milliamperes. The third constant trickle current is, for example but not limited to, 100 milliamperes. The constant current is, for example but not limited to, 1000 milliamperes.

Moreover, the universal serial bus unit 102 is, for example but not limited to, a micro universal serial bus. The charging unit 104 is, for example but not limited to, a charging circuit. The control unit 106 is, for example but not limited to, a microprocessor or a microcontroller. The electricity storage unit 108 is, for example but not limited to, a rechargeable lithium battery. The voltage detection unit 110 is, for example but not limited to, a voltage detection circuit or a voltage detector. The motor unit 114 is, for example but not limited to, an electric tool motor.

Moreover, the switch unit 112 is, for example but not limited to, a power switch for controlling the electricity storage unit 108 to supply power to the motor unit 114. The electricity storage unit 108 supplies power to the motor unit 114 when the switch unit 112 is turned on. The electricity storage unit 108 does not supply power to the motor unit 114 when the switch unit 112 is turned off.

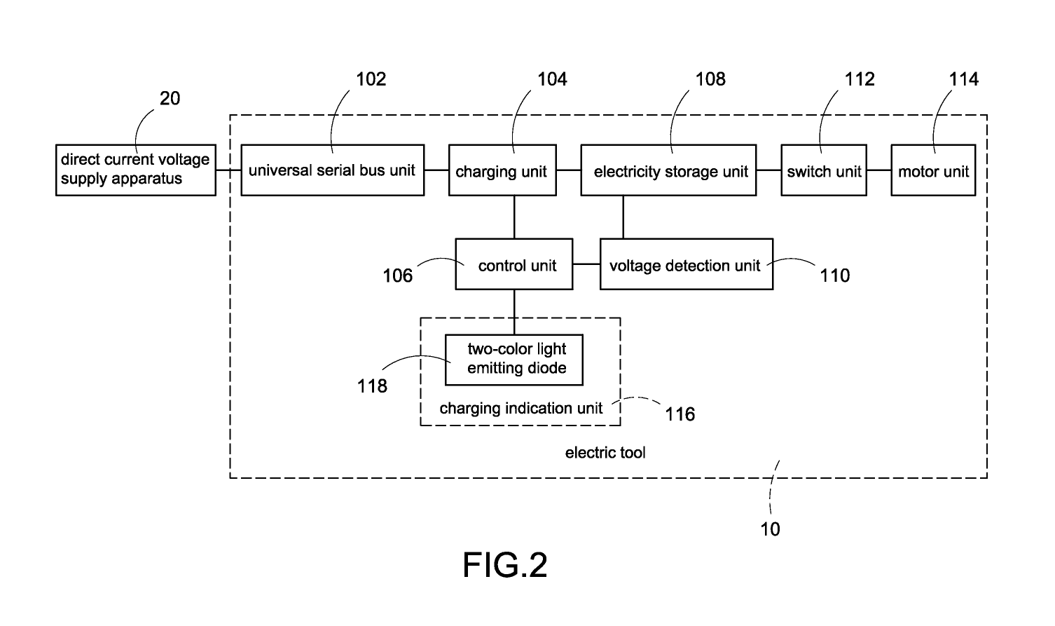

FIG. 2 shows a block diagram of the second embodiment of the electric tool of the present invention. The description for the elements shown in FIG. 2, which are similar to those shown in FIG. 1, is not repeated here for brevity. Moreover, the electric tool 10 further comprises a charging indication unit 116 electrically connected to the control unit 106. The charging indication unit 116 comprises a two-color light emitting diode 118 electrically connected to the control unit 106. The two-color light emitting diode 118 glows red light or green light. The control unit 106 is configured to control the two-color light emitting diode 118 to glow red light when the electricity storage unit 108 is charged. The control unit 106 is configured to control the two-color light emitting diode 118 to glow green light when the electricity storage unit 108 is not charged.

The advantages of the present invention are that the charging method for the electric tool is more convenient (namely, the direct current voltage supply apparatus 20 supplies power through the universal serial bus unit 102 to the charging unit 104) and the charging efficiency is improved.

Although the present invention has been described with reference to the preferred embodiment thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. An electric tool applied to a direct current voltage supply apparatus, the electric tool electrically connected to the direct current voltage supply apparatus, the electric tool comprising:
a universal serial bus unit electrically connected to the direct current voltage supply apparatus;
a charging unit electrically connected to the universal serial bus unit;
a control unit electrically connected to the charging unit;
an electricity storage unit electrically connected to the charging unit;
a voltage detection unit electrically connected to the electricity storage unit and the control unit;
a switch unit electrically connected to the electricity storage unit; and
a motor unit electrically connected to the switch unit,
wherein the voltage detection unit detects a voltage of the electricity storage unit and then informs the control unit of the voltage of the electricity storage unit; if the voltage of the electricity storage unit is not greater than a first threshold voltage, the control unit is configured to control the charging unit to charge the electricity storage unit with a first constant trickle current until the voltage of the electricity storage unit is greater than the first threshold voltage;
wherein if the voltage of the electricity storage unit is greater than the first threshold voltage, the control unit is configured to control the charging unit to charge the electricity storage unit with a constant current until the voltage of the electricity storage unit is greater than or equal to a second threshold voltage;
wherein if the voltage of the electricity storage unit is greater than or equal to the second threshold voltage, the control unit is configured to control the charging unit to charge the electricity storage unit with a constant voltage until a current for charging the electricity storage unit is equal to a second constant trickle current, and then the charging unit stops charging the electricity storage unit;
wherein after the electricity storage unit is full charged, when a transient voltage of the electricity storage unit is decreased and is less than or equal to a third threshold voltage, the control unit is configured to control the charging unit to float charge the electricity storage unit until the current for charging the electricity storage unit is equal to a third constant trickle current and until the transient voltage of the electricity storage unit is greater than the third threshold voltage; then the charging unit stops float charging the electricity storage unit;
wherein the second threshold voltage is greater than the first threshold voltage; the second threshold voltage is greater than the third threshold voltage; the third threshold voltage is greater than the first threshold voltage; the constant current is greater than the first constant trickle current; the constant current is greater than the second constant trickle current; the constant current is greater than the third constant trickle current.

2. The electric tool in claim 1, further comprising a charging indication unit electrically connected to the control unit.

3. The electric tool in claim 2, wherein the charging indication unit comprises a two-color light emitting diode electrically connected to the control unit; the two-color light emitting diode glows red light or green light;
wherein the control unit is configured to control the two-color light emitting diode to glow red light when the electricity storage unit is charged; the control unit is configured to control the two-color light emitting diode to glow green light when the electricity storage unit is not charged.

4. The electric tool in claim 3, wherein the first threshold voltage is 2.5 volts; the second threshold voltage is stable 3.6 volts; the third threshold voltage is 3.3 volts; the first constant trickle current is 100 milliamperes; the second constant trickle current is 100 milliamperes; the third constant trickle current is 100 milliamperes; the constant current is 1000 milliamperes.

5. The electric tool in claim 4, wherein the universal serial bus unit is a micro universal serial bus; the charging unit is a charging circuit.

6. The electric tool in claim 5, wherein the control unit is a microprocessor or a microcontroller.

7. The electric tool in claim 6, wherein the electricity storage unit is a rechargeable lithium battery.

8. The electric tool in claim 7, wherein the voltage detection unit is a voltage detection circuit or a voltage detector.

9. The electric tool in claim 8, wherein the switch unit is a power switch for controlling the electricity storage unit to supply power to the motor unit; the electricity storage unit supplies power to the motor unit when the switch unit is turned on; the electricity storage unit does not supply power to the motor unit when the switch unit is turned off.

10. The electric tool in claim 9, wherein the motor unit is an electric tool motor.
